(19) United States
(12) Patent Application Publication
(10) Pub. No.: US 2025/0132227 A1
(43) Pub. Date: Apr. 24, 2025

(54) SEMICONDUCTOR PACKAGE

(71) Applicant: Samsung Electronics Co., Ltd., Suwon-si (KR)

(72) Inventors: Hansung RYU, Suwon-si (KR); Jongbeom PARK, Suwon-si (KR)

(73) Assignee: Samsung Electronics Co., Ltd., Suwon-si (KR)

(21) Appl. No.: 18/621,451

(22) Filed: Mar. 29, 2024

(30) Foreign Application Priority Data
Oct. 20, 2023 (KR) 10-2023-0141230

(51) Int. Cl. H01L 23/48; H01L 23/00; H01L 23/522

(52) U.S. Cl. CPC H01L 23/481; H01L 23/5226; H01L 24/08; H01L 2224/08145

(57) ABSTRACT

A semiconductor package may include a first semiconductor chip and a second semiconductor chip below the first semiconductor chip. The first semiconductor chip may include a first semiconductor substrate, a first semiconductor device and a first interconnection layer on a bottom surface of the first semiconductor substrate, a first via penetrating the first semiconductor substrate and electrically connected to the first interconnection layer, and a first pad on a bottom surface of the first interconnection layer. The second semiconductor chip may include a second semiconductor substrate, a second via penetrating the second semiconductor substrate, and a second pad on a top surface of the second semiconductor substrate and electrically connected to the second via. The first and second vias may be shifted from each other in a horizontal direction, and the first via may be horizontally spaced apart from the first pad, when viewed in a plan view.

### CROSS-REFERENCE TO RELATED APPLICATIONS

This U.S. non-provisional patent application claims priority under 35 U.S.C. § 119 to Korean Patent Application No. 10-2023-0141230, filed on Oct. 20, 2023, in the Korean Intellectual Property Office, the entire contents of which are hereby incorporated by reference.

### BACKGROUND

The present disclosure relates to semiconductor packages, and in particular, to stack-type semiconductor packages.

In the semiconductor industry, various package technologies have been developed in order to respond to an increase in demand for large-capacity, thin, and small semiconductor packages and/or electronic products therewith. For example, a package technology of vertically stacking semiconductor chips has been suggested to realize a high-density chip stacking structure. This technology makes it possible to integrate semiconductor chips of various functions on a small area, compared with a typical package provided in the form of a single semiconductor chip.

A semiconductor package includes a semiconductor chip that is provided to be easily used as a part of an electronic product. In general, the semiconductor package includes a printed circuit board (PCB) and a semiconductor chip, which is mounted on the PCB and is electrically connected to the PCB using bonding wires or bumps. With the development of the electronic industry, various studies are being conducted to improve reliability and durability of the semiconductor package.

### SUMMARY

An example embodiment of the inventive concepts provides a semiconductor package with improved structural stability.

An example embodiment of the inventive concepts provides a semiconductor package with improved electrical characteristics.

According to an example embodiment of the inventive concepts, a semiconductor package includes a first semiconductor chip and a second semiconductor chip below the first semiconductor chip. The first semiconductor chip includes a first semiconductor substrate, a first semiconductor device on a bottom surface of the first semiconductor substrate, a first interconnection layer on the bottom surface of the first semiconductor substrate, a first via vertically penetrating the first semiconductor substrate and electrically connected to the first interconnection layer, and a first pad on a bottom surface of the first interconnection layer. The second semiconductor chip includes a second semiconductor substrate, a second via vertically penetrating the second semiconductor substrate, and a second pad on a top surface of the second semiconductor substrate and electrically connected to the second via. The first semiconductor chip and the second semiconductor chip is in direct contact with each other, and the first pad and the second pad includes a same material and constitutes a single integral object. The first and second vias is shifted from each other in a direction parallel to the bottom surface of the first semiconductor substrate, and the first via is horizontally spaced apart from the first pad, when viewed in a plan view, and is electrically connected to the second pad through the first interconnection layer.

According to an example embodiment of the inventive concepts, a semiconductor package includes a first semiconductor chip and a second semiconductor chip on the first semiconductor chip. The first semiconductor chip includes a first semiconductor substrate, a first semiconductor device on a bottom surface of the first semiconductor substrate, a first interconnection layer on the bottom surface of the first semiconductor substrate, a first via vertically penetrating the first semiconductor substrate and electrically connected to the first interconnection layer, a redistribution layer on a top surface of the first semiconductor substrate, and a first pad on a top surface of the redistribution layer. The second semiconductor chip includes a second semiconductor substrate, a second semiconductor device on a bottom surface of the second semiconductor substrate, a second interconnection layer on the bottom surface of the second semiconductor substrate, a second via vertically penetrating the second semiconductor substrate and electrically connected to the second interconnection layer, and a second pad on a bottom surface of the second interconnection layer. The first via and the second via are vertically aligned to each other, and the first pad and the second pad are vertically aligned to each other. Respective sets of the first and second vias are shifted from corresponding sets of the first and second pads, respectively, in a direction parallel to the top surface of the first semiconductor substrate by a distance that is 0.5 to 5 times a sum of a width of the first via and a width of the first pad or a sum of a width of the second via and a width of the second pad.

According to an example embodiment of the inventive concepts, a semiconductor package includes a substrate, a first semiconductor chip on the substrate, a second semiconductor chip below the first semiconductor chip, and a mold layer on the substrate and enclosing the first and second semiconductor chips. The first semiconductor chip includes a first semiconductor substrate, a first semiconductor device on a bottom surface of the first semiconductor substrate, a first interconnection layer on the bottom surface of the first semiconductor substrate, first vias vertically penetrating the first semiconductor substrate and electrically connected to the first interconnection layer, and first pads on a bottom surface of the first interconnection layer. The second semiconductor chip includes a second semiconductor substrate, second vias vertically penetrating the second semiconductor substrate, and second pads on a top surface of the second semiconductor substrate. The first semiconductor chip and the second semiconductor chip are in direct contact with each other, and each of the first pads and a corresponding one of the second pads includes a same material and constitute a single integral object. When viewed in a plan view, the first vias are in a lattice shape, and the first pads are in a lattice shape. Each of the first pads is between four adjacent ones of the first vias them.

### BRIEF DESCRIPTION OF THE DRAWINGS

FIG. 1 is a sectional view illustrating a semiconductor package according to an example embodiment of the inventive concepts.

FIGS. 2 to 5 are plan views illustrating an arrangement of pads and vias in a semiconductor package according to an example embodiment of the inventive concepts.

FIGS. 6 to 8 are sectional views illustrating a semiconductor package according to an example embodiment of the inventive concepts.

FIG. 9 is a sectional view illustrating a semiconductor package according to an example embodiment of the inventive concepts.

FIGS. 10 to 13 are sectional views illustrating structures of semiconductor chips bonded to each other.

FIG. 14 is a sectional view illustrating a semiconductor package according to an example embodiment of the inventive concepts.

FIGS. 15 to 17 are sectional views illustrating structures of semiconductor chips bonded to each other.

### DETAILED DESCRIPTION

Example embodiments of the inventive concepts will now be described more fully with reference to the accompanying drawings, in which some example embodiments are shown.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., +10%).

When the term “about,” “substantially” or “approximately” is used in this specification in connection with a numerical value, it is intended that the associated numerical value includes a manufacturing or operational tolerance (e.g., +10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

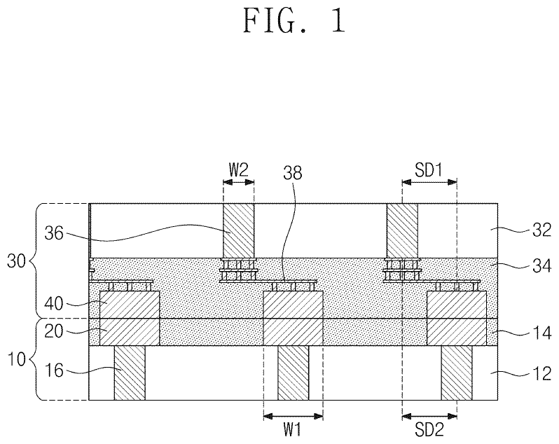

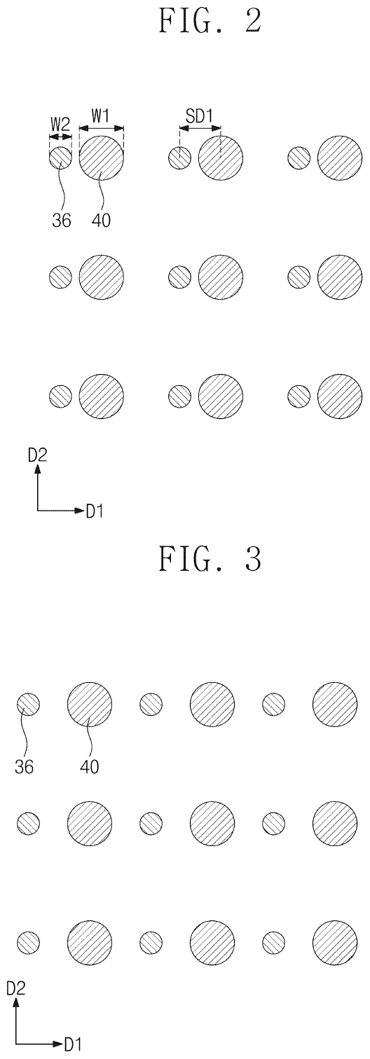

FIG. 1 is a sectional view illustrating a semiconductor package according to an example embodiment of the inventive concepts. FIGS. 2 to 5 are plan views illustrating an arrangement of pads and vias in a semiconductor package according to an example embodiment of the inventive concepts.

Referring to FIG. 1, a semiconductor package may include a lower structure 10 and an upper structure 30 stacked thereon.

The lower structure 10 may include a first device layer 12, a first insulating layer 14, and first pads 20.

The first device layer 12 may include a semiconductor device. For example, the first device layer 12 may include a first semiconductor substrate and a first circuit layer thereon.

The first semiconductor substrate may be a semiconductor substrate (e.g., a semiconductor wafer). The first semiconductor substrate may be a bulk silicon substrate, a silicon-on-insulator (SOI) substrate, a germanium substrate, a germanium-on-insulator (GOI) substrate, a silicon-germanium substrate, or a substrate including an epitaxial thin film formed by a selective epitaxial growth (SEG). The first semiconductor substrate may be formed of or include at least one of, for example, silicon (Si), germanium (Ge), silicon germanium (SiGe), gallium arsenic (GaAs), indium gallium arsenic (InGaAs), or aluminum gallium arsenic (AlGaAs). In some example embodiments, the first semiconductor substrate may be an insulating substrate.

The first circuit layer may be provided on the first semiconductor substrate. The first circuit layer may include a first circuit pattern provided on a top surface of the first semiconductor substrate and an insulating layer covering the first circuit pattern. The first circuit pattern may be a memory circuit, a logic circuit, or combinations thereof including one or more transistors. In some example embodiments, the first circuit pattern may include a passive device, such as a resistor or a capacitor. In an example embodiment, the first circuit pattern may include interconnection patterns electrically connected to the transistors or the passive device.

The first pads 20 may be disposed on the first device layer 12. The first pads 20 may have a damascene structure. For example, the first pad 20 may further include a seed layer or a barrier layer, which is provided to cover side and bottom surfaces thereof. The first pad 20 may have a plate shape or a tapered shape having a width that decreases as a distance to the first device layer 12 decreases. For example, the first pads 20 may have a tetragonal, rectangular, or parallelogram shape, when viewed in a sectional view. Unlike the illustrated structure, the first pad 20 may include a via portion and a pad portion, which are sequentially stacked and are connected to each other to form a single object, and may have a ‘T’-shaped section. The first pads 20 may have a circular shape, when viewed in a plan view. In some example embodiments, the first pads 20 may have a tetragonal or rectangular shape, when viewed in a plan view. However, the inventive concepts are not limited to this example, and the planar shape of the first pads 20 may be variously changed, if desired. The first pads 20 may include at least one of metallic materials. As an example, the first pads 20 may be formed of or include copper (Cu).

The first pads 20 may be electrically connected to the first circuit pattern of the first device layer 12. For example, first interconnection lines 16 may be provided in the first device layer 12, as shown in FIG. 1. The first interconnection lines 16 may be penetration vias, which are provided to vertically penetrate an insulating pattern in the first device layer 12. The first interconnection lines 16 may be pillar-shaped patterns that are placed in the first device layer 12 and are extended in a vertical direction. In the first device layer 12, the first interconnection lines 16 may be vertically extended and may be coupled to the first pads 20. The first interconnection lines 16 may electrically connect the first circuit pattern to the first pads 20. A planar area of the first pad 20 may be larger than a planar area of the first interconnection line 16. For example, a width of the first pads 20 may be larger than a width of the first interconnection lines 16. The first interconnection lines 16 may include a metallic material (e.g., tungsten (W)). Although not shown in FIG. 1, various conductive patterns constituting an interconnection structure may be provided between the first circuit pattern and the first interconnection lines 16.

The first insulating layer 14 may be disposed on the first device layer 12. The first insulating layer 14 on the first device layer 12 may enclose the first pads 20. Top surfaces of the first pads 20 may be exposed to the outside of the first insulating layer 14. A top surface of the first insulating layer 14 may be coplanar with the top surfaces of the first pads 20. The first insulating layer 14 may be formed of or include at least one of oxide, nitride or oxynitride materials, which contains an element constituting the first device layer 12. The first insulating layer 14 may be formed of or include at least one of insulating materials (e.g., silicon oxide (SiO), silicon nitride (SiN), silicon oxynitride (SiON), or silicon carbon nitride (SiCN)).

The upper structure 30 may include a second device layer 32, a second insulating layer 34, and second pads 40.

The second device layer 32 may include a semiconductor device. For example, the second device layer 32 may include a second semiconductor substrate and a second circuit layer thereon.

The second semiconductor substrate may be a semiconductor substrate (e.g., a semiconductor wafer). The second semiconductor substrate may be a bulk silicon substrate, a silicon-on-insulator (SOI) substrate, a germanium substrate, a germanium-on-insulator (GOI) substrate, a silicon-germanium substrate, or a substrate including an epitaxial thin film formed by a selective epitaxial growth (SEG). The second semiconductor substrate may be formed of or include at least one of, for example, silicon (Si), germanium (Ge), silicon germanium (SiGe), gallium arsenic (GaAs), indium gallium arsenic (InGaAs), or aluminum gallium arsenic (AlGaAs). In some example embodiments, the second semiconductor substrate may be an insulating substrate.

The second circuit layer may be provided on the second semiconductor substrate. The second circuit layer may include a second circuit pattern provided on a bottom surface of the second semiconductor substrate and an insulating layer covering the second circuit pattern. The second circuit pattern may be a memory circuit, a logic circuit, or combinations thereof including one or more transistors. In some example embodiments, the second circuit pattern may include a passive device, such as a resistor or a capacitor. In an embodiment, the second circuit pattern may include interconnection patterns electrically connected to the transistors or the passive device.

Second interconnection lines 36 may be provided in the second device layer 32. For example, as shown in FIG. 1, the second interconnection lines 36 may be penetration vias, which are provided to vertically penetrate an insulating pattern in the second device layer 32. The second interconnection lines 36 may be pillar-shaped patterns that are placed in the second device layer 32 and are extended in a vertical direction. The second interconnection lines 36 may be electrically connected to the second circuit pattern. The second interconnection lines 36 may include a metallic material (e.g., tungsten (W)). Although not shown in FIG. 1, various conductive patterns constituting an interconnection structure may be provided between the second circuit pattern and the second interconnection lines 36.

The second pads 40 may be disposed on the second device layer 32. The second pads 40 may have a damascene structure. For example, the second pad 40 may further include a seed layer or a barrier layer, which is provided to cover side and bottom surfaces thereof. The second pads 40 may have a plate shape or a tapered shape having a width that decreases as a distance to the second device layer 32 decreases. In an example embodiment, the second pad 40 may have a triangle or parallelogram shape, when viewed in a sectional view. Unlike the illustrated structure, the second pad 40 may include a via portion and a pad portion, which are sequentially stacked and are connected to each other to form a single object, and may have a ‘T’-shaped section. The second pad 40 may have a circular shape, when viewed in a plan view. In an example embodiment, the second pad 40 may have a tetragonal shape, when viewed in a plan view. However, the inventive concepts are not limited to this example, and the planar shape of the second pads 40 may be variously changed, if desired. A planar area of the second pad 40 may be larger than a planar area of the second interconnection line 36. For example, a width of the second pads 40 may be larger than a width of the second interconnection lines 36. The second pads 40 may be vertically spaced apart from a bottom surface of the second device layer 32. The second pads 40 may include at least one of metallic materials. As an example, the second pads 40 may be formed of or include copper (Cu).

The second pads 40 may be horizontally shifted from the second interconnection lines 36. The following description will be given based on the second pad 40 and the second interconnection line 36 that are paired and electrically connected to each other. For example, the second pad 40 may not vertically overlap the second interconnection line 36. As an example, a side surface of the second pad 40 may be spaced apart from a side surface of the second interconnection line 36, when viewed in a plan view. For example, a shift distance SD1 between the second pad 40 and the second interconnection line 36 may be larger than half the sum of a first width W1 of the second pad 40 and a second width W2 of the second interconnection line 36. In the present specification, a shift distance between the second pad 40 and the second interconnection line 36 may mean a distance between a vertical center axis of the second pad 40 and a vertical center axis of the second interconnection line 36 in a horizontal direction. Here, a shift direction between the second pad 40 and the second interconnection line 36 may be parallel to a top surface of the lower structure 10 or a bottom surface of the upper structure 30 or may be a horizontal direction.

The arrangement of the second pads 40 and the second interconnection lines 36 will be described in more detail below. The following description will be given based on the second pad 40 and the second interconnection line 36 that are paired and electrically connected to each other.

Referring to FIG. 2, the second pads 40 may be arranged in a lattice shape. For example, the second pads 40 may be arranged in a first direction D1 and a second direction D2. The second interconnection lines 36 may be arranged in a lattice shape. For example, the second interconnection lines 36 may be arranged in the first and second directions D1 and D2. The second pads 40 may be aligned to the second interconnection lines 36 in the first direction D1. As an example, each of the second pads 40 may be placed at a position that is spaced apart from a corresponding one of the second interconnection lines 36 in the first direction D1. Each of the second pads 40 may be placed between two lines of the second interconnection lines 36, which are adjacent to each other in the first direction D1. For the second pad 40 and the second interconnection line 36 that are paired and electrically connected to each other, the second pad 40 may be disposed adjacent to the second interconnection line 36, which is paired with the same, and may be disposed far from another second interconnection line 36, which is adjacent to the same in the first direction D1. For example, each of the second pads 40 may be placed between the second interconnection lines 36 and may be adjacent to one of the second interconnection lines 36 electrically connected thereto.

In an example embodiment, each of the second pads 40 may be placed between the second interconnection lines 36 in the first direction D1, as shown in FIG. 3. Here, each of the second pads 40 may be disposed to be spaced apart from a pair of the second interconnection lines 36 by the same distance in the first direction D1. For example, the second pads 40 and the second interconnection lines 36 may be alternately arranged to be spaced apart from each other by the same distance in the first direction D1.

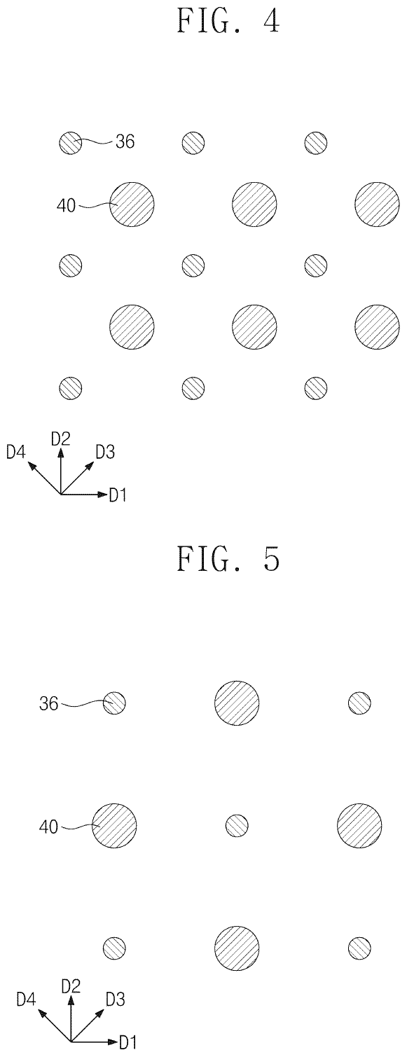

In an example embodiment, the second pads 40 may be arranged in a lattice shape, as shown in FIG. 4. The second interconnection lines 36 may also be arranged in a lattice shape. Here, each of the second pads 40 may be placed between four second interconnection lines 36, which are adjacent to each other. For example, the second pads 40 and the second interconnection lines 36 may be alternately arranged in a third direction D3 and a fourth direction D4 that are not parallel to the first and second directions D1 and D2 and are orthogonal to each other. Here, a distance between the second pads 40 and the second interconnection lines 36 may be substantially uniform. In an example embodiment, each of the second pads 40 may be disposed adjacent to one of the second interconnection lines 36, which is electrically connected to the same, and may be disposed far from the others of the second interconnection lines 36 therearound.

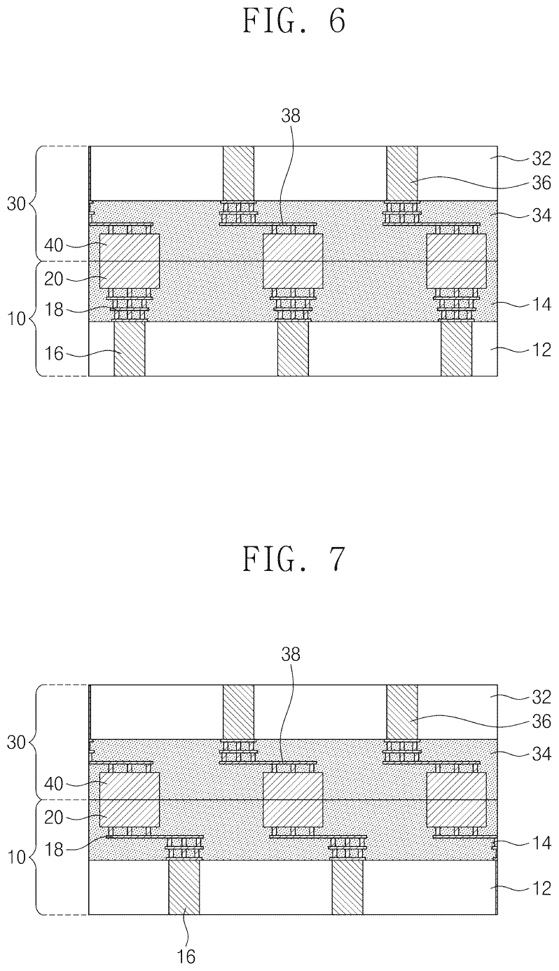

In an example embodiment, the second pads 40 may be arranged in the third and fourth directions D3 and D4, as shown in FIG. 5. The second interconnection lines 36 may also be arranged in the third and fourth directions D3 and D4. Here, each of the second pads 40 may be placed between four second interconnection lines 36, which are adjacent to each other. For example, the second pads 40 and the second interconnection lines 36 may be alternately arranged in the first and second directions D1 and D2. Here, a distance between the second pads 40 and the second interconnection lines 36 may be substantially uniform. In an example embodiment, each of the second pads 40 may be disposed adjacent to one of the second interconnection lines 36, which is electrically connected to the same, and may be disposed far from the others of the second interconnection lines 36 therearound.

However, the arrangement of the second pads 40 and the second interconnection lines 36 is not limited to the above examples and may be variously changed, if desired.

Referring back to FIG. 1, the second insulating layer 34 may be disposed on the second device layer 32. The second insulating layer 34 on the second device layer 32 may enclose the second pads 40. Bottom surfaces of the second pads 40 may be exposed to the outside of the second insulating layer 34. A bottom surface of the second insulating layer 34 may be coplanar with the bottom surfaces of the second pads 40. The second insulating layer 34 may be in contact with the bottom surface of the second device layer 32. A thickness of the second insulating layer 34 may be thicker than a thickness of the second pads 40. In other words, the second pads 40 may be placed in a lower portion of the second insulating layer 34. The second insulating layer 34 may be formed of or include at least one of oxide, nitride or oxynitride materials, which contains an element constituting the second device layer 32. The second insulating layer 34 may be formed of or include at least one of insulating materials (e.g., silicon oxide (SiO), silicon nitride (SiN), silicon oxynitride (SiON), or silicon carbon nitride (SiCN)).

A first interconnection pattern 38 may be provided in the second insulating layer 34. When in a sectional view, the first interconnection pattern 38 may be placed between the second pads 40 and the second device layer 32. The first interconnection pattern 38 may electrically connect the second pads 40 to the second interconnection lines 36. The first interconnection pattern 38 may include horizontal interconnection patterns and vertical interconnection patterns. The vertical interconnection patterns may connect the horizontal interconnection patterns to each other, connect the horizontal interconnection patterns to the second interconnection lines 36, and connect the horizontal interconnection patterns to the second pads 40. The second pads 40 and the second interconnection lines 36, which are horizontally spaced apart from each other, may be electrically connected to each other by the first interconnection pattern 38. In an example embodiment, a portion of the second insulating layer 34 and the first interconnection pattern 38, which are located between the second pads 40 and the second device layer 32, may correspond to an interconnection layer, which connects the second interconnection lines 36 to the second pads 40.

The upper structure 30 may be disposed on the lower structure 10. The first pads 20 of the lower structure 10 may be vertically aligned to the second pads 40 of the upper structure 30. The first interconnection lines 16 may be horizontally shifted from the second interconnection lines 36. A shift distance SD2 between the first and second interconnection lines 16 and 36 may be larger than half the sum of the first width W1 of the second pad 40 and the second width W2 of the second interconnection line 36. In addition, the first interconnection lines 16, the first pads 20, and the second pads 40 may be vertically aligned to each other. The lower structure 10 and the upper structure 30 may be in contact with each other such that the first pads 20 are connected to the second pads 40.

At an interface between the lower structure 10 and the upper structure 30, the first insulating layer 14 of the lower structure 10 may be bonded to the second insulating layer 34 of the upper structure 30. Here, the first and second insulating layers 14 and 34 may form a hybrid bonding structure of oxide, nitride, or oxynitride. In the present specification, the hybrid bonding structure may mean a bonding structure that is formed by two materials, which are of the same kind and are fused at an interface therebetween. For example, the first and second insulating layers 14 and 34, which are bonded to each other, may have a continuous structure, and there may be no visible interface between the first and second insulating layers 14 and 34. For example, the first and second insulating layers 14 and 34 may be formed of the same material, and there may be no interface between the first and second insulating layers 14 and 34. That is, the first and second insulating layers 14 and 34 may be provided as a single object (e.g., an integral body). For example, the first and second insulating layers 14 and 34 may be bonded to each other to form a single object. However, the inventive concepts are not limited to this example. The first and second insulating layers 14 and 34 may be formed of different materials. The first and second insulating layers 14 and 34 may not have a continuous structure, and there may be an observable or visible interface between the first and second insulating layers 14 and 34. The first and second insulating layers 14 and 34 may not be bonded to each other, and each of the first and second insulating layers 14 and 34 may be provided as an individual element. Hereinafter, the inventive concepts will be further described with reference to the example embodiment of FIG. 1.

The upper structure 30 may be connected to the lower structure 10. For example, the lower structure 10 and the upper structure 30 may be in contact with each other. At an interface between the lower structure 10 and the upper structure 30, the first pads 20 of the lower structure 10 may be bonded to the second pads 40 of the upper structure 30. Here, the first and second pads 20 and 40 may form an intermetal hybrid bonding structure. For example, the first and second pads 20 and 40, which are bonded to each other, may have a continuous structure, and there may be no visible interface between the first pads 20 and the second pads 40. When the first pads 20 and the second pads 40 are formed of the same material, there may be no interface between the first pads 20 and the second pads 40. That is, the first and second pads 20 and 40 may be provided as a single object. For example, the first and second pads 20 and 40 may be bonded to each other to form a single object.

The first interconnection lines 16 may be formed of or include a material different from the first semiconductor substrate and the first circuit layer constituting the first device layer 12. Thus, a vertical stress in the lower structure 10 may be concentrated on the first interconnection lines 16. For example, a thermal stress on the first interconnection lines 16 may be increased by heat generated during a process of fabricating or operating the semiconductor package. This is because the first interconnection lines 16 are formed of a material having a different thermal expansion coefficient from the first semiconductor substrate and the first circuit layer.

The second interconnection lines 36 may be formed of or include a material different from the second semiconductor substrate and the second circuit layer constituting the second device layer 32. Thus, the vertical stress in the upper structure 30 may be concentrated on the second interconnection lines 36. For example, a thermal stress on the second interconnection lines 36 may be increased by heat generated during a process of fabricating or operating the semiconductor package. This is because the second interconnection lines 36 are formed of a material having a different thermal expansion coefficient from the second semiconductor substrate and the second circuit layer.

According to an example embodiment of the inventive concepts, the first interconnection lines 16 vertically penetrating the lower structure 10 may be disposed to be horizontally shifted from the second interconnection lines 36 vertically penetrating the upper structure 30. Thus, stresses, which are exerted on the first and second interconnection lines 16 and 36 in a vertical direction, may not overlap each other. In this case, the stress exerted on the first interconnection lines 16 may be dispersed into the first insulating layer 14, in a region on the first interconnection lines 16, or may be transferred to and dispersed into the second insulating layer 34 through the second and first pads 40 and 20. The stress exerted on the second interconnection lines 36 may be dispersed into the second insulating layer 34, in a region below the second interconnection lines 36. Thus, it may be possible to improve the structural characteristics of the semiconductor package. In addition, it may be possible to mitigate or prevent a delamination issue between the first and second interconnection lines 16 and 36 and the first and second pads 20 and 40 that is caused by the stresses, and thereby to improve the electric connection characteristics between the first and second interconnection lines 16 and 36 and the first and second pads 20 and 40. That is, a semiconductor package with improved electrical characteristics may be provided.

In the description of the example embodiments to be explained below, an element previously described with reference to FIGS. 1 to 5 may be identified by the same reference number without repeating an overlapping description thereof, for concise description.

FIG. 6 is a sectional view illustrating a semiconductor package according to an example embodiment of the inventive concepts.

Referring to FIG. 6, the first pads 20 may be disposed on the first device layer 12. The first pads 20 may be vertically spaced apart from a top surface of the first device layer 12. The first pads 20 may be vertically aligned to the first interconnection lines 16.

The first insulating layer 14 may be disposed on the first device layer 12. The first insulating layer 14 on the first device layer 12 may enclose the first pads 20. Top surfaces of the first pads 20 may be exposed to the outside of the first insulating layer 14. A top surface of the first insulating layer 14 may be coplanar with the top surfaces of the first pads 20. The first insulating layer 14 may be in contact with the top surface of the first device layer 12. A thickness of the first insulating layer 14 may be larger than a thickness of the first pads 20. That is, the first pads 20 may be placed in an upper portion of the first insulating layer 14.

A second interconnection pattern 18 may be provided in the first insulating layer 14. When viewed in a vertical sectional view, the second interconnection pattern 18 may be placed between the first pads 20 and the first device layer 12. The second interconnection pattern 18 may electrically connect the first pads 20 to the first interconnection lines 16. The second interconnection pattern 18 may include horizontal interconnection patterns and vertical interconnection patterns. The vertical interconnection patterns may be provided to connect the horizontal interconnection patterns to each other, connect the horizontal interconnection patterns to the first interconnection lines 16, and connect the horizontal interconnection patterns to the first pads 20. The first pads 20 and the first interconnection lines 16 that are horizontally spaced apart from each other, may be electrically connected to each other by the second interconnection pattern 18. In an example embodiment, the second interconnection pattern 18, which is located between the first pads 20 and the first device layer 12, may correspond to an interconnection layer, which connects the first interconnection lines 16 to the first pads 20.

FIG. 7 is a sectional view illustrating a semiconductor package according to an example embodiment of the inventive concepts.

FIG. 6 illustrates an example, in which the first pads 20 are vertically aligned to the first interconnection lines 16, but the inventive concepts are not limited to this example.

Referring to FIG. 7, the first pads 20 may be horizontally shifted from the first interconnection lines 16. The following description will be given based on the first pad 20 and the first interconnection line 16 that are paired and electrically connected to each other. For example, the first pad 20 may not vertically overlap the first interconnection line 16. When viewed in a plan view, a side surface of the first pad 20 may be spaced apart from a side surface of the first interconnection line 16. For example, a shift distance between the first pad 20 and the first interconnection line 16 may be larger than half the sum of a width of the first pad 20 and a width of the first interconnection line 16. In the present specification, the shift distance between the first pad 20 and the first interconnection line 16 may mean a distance between a vertical center axis of the first pad 20 and a vertical center axis of the first interconnection line 16 in a horizontal direction. Here, a shift direction between the first pad 20 and the first interconnection line 16 may be parallel to the top surface of the lower structure 10 or the bottom surface of the upper structure 30, or may be a horizontal direction.

The arrangement of the first pads 20 and the first interconnection lines 16 in a plan view may be the same as or similar to that of the second pads 40 and the second interconnection lines 36 described with reference to FIGS. 2 to 5.

The lower structure 10 and the upper structure 30 may be in contact with each other. At an interface between the lower structure 10 and the upper structure 30, the first pads 20 of the lower structure 10 may be bonded to the second pads 40 of the upper structure 30. The first pads 20 may be vertically aligned to the second pads 40. The first pads 20 and the second pads 40 may be horizontally spaced apart from the first interconnection lines 16 and may be horizontally spaced apart from the second interconnection lines 36. Here, when viewed in a plan view, the first and second pads 20 and 40 that are paired to each other may be placed between the first and second interconnection lines 16 and 36 which are connected thereto.

According to an example embodiment of the inventive concepts, the first and second interconnection lines 16 and 36 may be disposed to be horizontally shifted from each other, and the first and second pads 20 and 40 may be disposed to be shifted from the first and second interconnection lines 16 and 36, respectively. Thus, stresses, which are exerted on the first and second interconnection lines 16 and 36 in a vertical direction, may not overlap each other. In this case, the stress exerted on the first interconnection lines 16 may be dispersed into the first insulating layer 14, in a region on the first interconnection lines 16. The stress exerted on the second interconnection lines 36 may be dispersed into the second insulating layer 34, in a region below the second interconnection lines 36. In addition, the stress caused by the first and second interconnection lines 16 and 36 may not be transferred to the first and second pads 20 and 40. That is, the semiconductor package with improved structural characteristics may be provided.

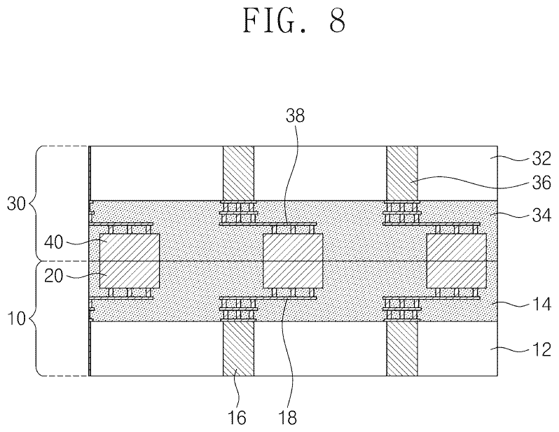

FIG. 8 is a sectional view illustrating a semiconductor package according to an example embodiment of the inventive concepts.

FIG. 7 illustrates an example, in which the first and second pads 20 and 40 are placed between the first and second interconnection lines 16 and 36 in a plan view, but the inventive concepts are not limited to this example.

Referring to FIG. 8, the first interconnection lines 16 may be vertically aligned to the second interconnection lines 36.

The first pads 20 may be horizontally shifted from the first interconnection lines 16. For the first pad 20 and the first interconnection line 16 that are paired and electrically connected to each other, the first pad 20 may not vertically overlap the first interconnection line 16. A shift distance between the first pad 20 and the first interconnection line 16 may be larger than half the sum of a width of the first pad 20 and a width of the first interconnection line 16.

The second pads 40 may be horizontally shifted from the second interconnection lines 36. For the second pad 40 and the second interconnection line 36 that are paired and electrically connected to each other, the second pad 40 may not vertically overlap the second interconnection line 36. A shift distance between the second pad 40 and the second interconnection line 36 may be larger than half the sum of a width of the second pad 40 and a width of the second interconnection line 36.

The first pads 20 may be vertically aligned to the second pads 40. Thus, a shift direction of the first pads 20 from the first interconnection lines 16 may be the same as a shift direction of the second pads 40 from the second interconnection lines 36.

According to an example embodiment of the inventive concepts, although the first interconnection lines 16 are vertically aligned to the second interconnection lines 36, the first and second pads 20 and 40 may be disposed to be horizontally shifted from the first and second interconnection lines 16 and 36, respectively. Thus, stresses, which are exerted on the first and second interconnection lines 16 and 36 in a vertical direction, may not overlap each other. In this case, the stress exerted on the first interconnection lines 16 may be dispersed into the first insulating layer 14, in a region on the first interconnection lines 16. The stress exerted on the second interconnection lines 36 may be dispersed into the second insulating layer 34, in a region below the second interconnection lines 36. In addition, the stress caused by the first and second interconnection lines 16 and 36 may not be transferred to the first and second pads 20 and 40. That is, the semiconductor package with improved structural characteristics may be provided.

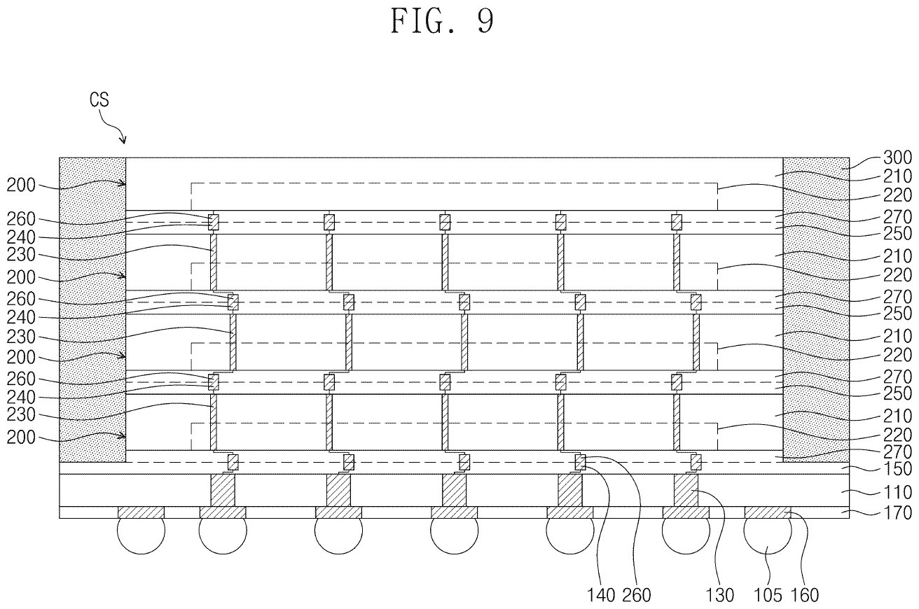

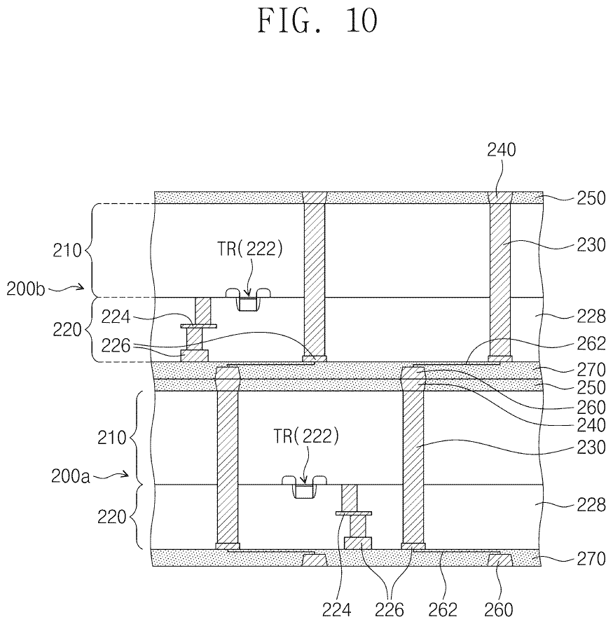

FIG. 9 is a sectional view illustrating a semiconductor package according to an example embodiment of the inventive concepts. FIG. 10 is a sectional view illustrating a structure of semiconductor chips bonded to each other.

Referring to FIG. 9, a base substrate 100 may be provided. The base substrate 100 may include an integrated circuit which is provided therein. For example, the base substrate 100 may be a first semiconductor chip including an electronic device (e.g., a transistor). For example, the base substrate 100 may be a wafer-level die that is formed of a semiconductor material (e.g., silicon (Si)). Although FIG. 1 illustrates an example in which the base substrate 100 is a first semiconductor chip, the inventive concepts are not limited to this example. In an example embodiment, the base substrate 100 may be a substrate (e.g., a printed circuit board (PCB)), in which an electronic element (e.g., a transistor) is not provided. A silicon wafer may be thinner than the printed circuit board (PCB). Hereinafter, the base substrate 100 may be referred to as a first semiconductor chip 100.

The first semiconductor chip 100 may include a first semiconductor substrate 110, a first via 130, a first upper pad 140, a first upper protection layer 150, a first lower pad 160, and a first lower protection layer 170.

The first semiconductor substrate 110 may be provided. The first semiconductor substrate 110 may include a semiconductor material. For example, the first semiconductor substrate 110 may be a single crystalline silicon substrate.

Although not shown, a first circuit layer may be provided on a bottom surface of the first semiconductor substrate 110. The first circuit layer may include the afore-described integrated circuit. For example, the first circuit layer may be a memory circuit, a logic circuit, or combinations thereof. A bottom surface of the first semiconductor chip 100, on which the first circuit layer is provided, may be an active surface. However, in an example embodiment, the first circuit layer may not be provided. In this case, a base substrate, in which an electronic device (e.g., a transistor) is not included (or not formed), may be provided in place of the first semiconductor chip 100.

The first via 130 may be provided to vertically penetrate the first semiconductor substrate 110. For example, the first via 130 may connect a top surface of the first semiconductor substrate 110 to the first circuit layer. The first via 130 and the first circuit layer may be electrically connected to each other. In an example embodiment, a plurality of first vias 130 may be provided. If desired, an insulating layer (not shown) may be provided to enclose the first via 130. For example, the insulating layer may be formed of or include at least one of silicon oxide (SiO), silicon nitride (SiN), silicon oxynitride (SiON), or low-k dielectric materials.

The first upper pad 140 may be disposed on the top surface of the first semiconductor substrate 110. The first upper pad 140 may be coupled to the first via 130. In an example embodiment, a plurality of first upper pads 140 may be provided. In this case, the first upper pads 140 may be coupled to a plurality of first vias 130, respectively, and the arrangement of the first upper pads 140 may be substantially the same as the arrangement of the first vias 130. The first upper pad 140 may be coupled to the first circuit layer through the first via 130. The first upper pad 140 may be formed of or include at least one of metallic materials (e.g., copper (Cu), aluminum (Al), and/or nickel (Ni)).

The first upper protection layer 150 may be disposed on the top surface of the first semiconductor substrate 110 to enclose the first upper pad 140. The first upper protection layer 150 may be provided to expose the first upper pad 140. A top surface of the first upper protection layer 150 may be coplanar with a top surface of the first upper pad 140. The first semiconductor substrate 110 may be protected by the first upper protection layer 150. The first upper pad 140 may be connected to the first via 130. The first upper protection layer 150 may be formed of or include at least one of high density plasma (HDP) oxide, undoped silicate glass (USG), tetraethyl orthosilicate (TEOS), silicon nitride (SiN), silicon oxide (SiO), silicon oxycarbide (SiOC), silicon oxynitride (SiON), or silicon carbonitride (SiCN).

The first lower pad 160 may be disposed on the bottom surface of the first semiconductor substrate 110. For example, the first lower pad 160 may be disposed on the bottom surface of the first semiconductor substrate 110 or the bottom surface of the first circuit layer. The first lower pad 160 may be electrically connected to the first circuit layer. In an example embodiment, a plurality of first lower pads 160 may be provided. The first lower pad 160 may be formed of or include at least one of metallic materials (e.g., copper (Cu), aluminum (Al), and/or nickel (Ni)).

The first semiconductor chip 100 may further include the first lower protection layer 170. The first lower protection layer 170 may be disposed on the bottom surface of the first semiconductor substrate 110 to cover the first semiconductor substrate 110. The first lower protection layer 170 may be provided to expose the first lower pad 160 through a bottom surface thereof. The first circuit layer may be protected by the first lower protection layer 170. The first lower protection layer 170 may be an insulating coating layer including an epoxy resin.

An outer terminal 105 may be provided on the bottom surface of the first semiconductor chip 100. The outer terminal 105 may be disposed on the first lower pad 160. The outer terminal 105 may be electrically connected to the first semiconductor substrate 110 and the first via 130. In an example embodiment, the outer terminal 105 may be disposed below the first via 130. In this case, the first via 130 may be exposed to the outside of the first semiconductor substrate 110 through the bottom surface of the first semiconductor substrate 110, and the outer terminal 105 may be directly coupled to the first via 130. In an example embodiment, a plurality of outer terminals 105 may be provided. In this case, the outer terminals 105 may be coupled to the first lower pads 160, respectively. The outer terminal 105 may be formed of or include an alloy containing at least one of tin (Sn), silver (Ag), copper (Cu), nickel (Ni), bismuth (Bi), indium (In), antimony (Sb), or cerium (Ce).

A chip stack CS may be disposed on the first semiconductor chip 100. The chip stack CS may include a plurality of second semiconductor chips 200, which are vertically stacked. The second semiconductor chips 200 may be of the same kind. For example, the second semiconductor chips 200 may be memory chips. The second semiconductor chips 200 may be sequentially stacked on the first semiconductor chip 100. The present example embodiment refers to an example, in which four second semiconductor chips 200 are provided on the first semiconductor chip 100, but the inventive concepts are not limited to this example. In an example embodiment, two, three, five, or more second semiconductor chips 200 may be provided on the first semiconductor chip 100.

Hereinafter, second semiconductor chips 200, 200a, and 200b will be described in more detail with reference to FIGS. 9 and 10. Although, in FIG. 10, lower and upper ones of the second semiconductor chips are identified with two different reference numbers 200a and 200b for distinction purpose, each of the second semiconductor chips 200a and 200b of FIG. 10 may correspond to the second semiconductor chip 200 of FIG. 9.

Referring to FIGS. 9 and 10, each of the second semiconductor chips 200, 200a, and 200b may include a second semiconductor substrate 210, a second circuit layer 220, a second via 230, a second upper pad 240, a second upper protection layer 250, a second lower pad 260, and a second lower protection layer 270.

The second semiconductor substrate 210 may be provided. The second semiconductor substrate 210 may include a semiconductor material. For example, the second semiconductor substrate 210 may be a single crystalline silicon substrate. The second semiconductor substrate 210 may have a bottom surface and a top surface, which are opposite to each other. The bottom surface of the second semiconductor substrate 210 may be a front surface of the second semiconductor substrate 210, and the top surface may be a rear surface of the second semiconductor substrate 210. Here, the front surface of the second semiconductor substrate 210 may be defined as a surface of the second semiconductor substrate 210, on which semiconductor devices, interconnection lines, or pads are formed or mounted, and the rear surface of the second semiconductor substrate 210 may be defined as a surface that is opposite to the front surface. The front surface of the second semiconductor substrate 210 may face the first semiconductor chip 100. In other words, the bottom surface of the second semiconductor substrate 210 may be an active surface.

Each of the second semiconductor chips 200, 200a, and 200b may have the second circuit layer 220 facing the first semiconductor chip 100. The second circuit layer 220 may include a semiconductor device 222, a first interconnection portion 226, and a second interconnection portion 224.

The semiconductor device 222 may include transistors TR provided on the bottom surface of the second semiconductor substrate 210. The transistors TR may include source and drain regions, which are formed in a lower portion of the second semiconductor substrate 210, a gate electrode, which is disposed on the bottom surface of the second semiconductor substrate 210, and a gate insulating layer interposed between the second semiconductor substrate 210 and the gate electrode. FIG. 10 illustrates an example, in which one transistor TR is provided, but the inventive concepts are not limited to this example. The semiconductor device 222 may include a plurality of transistors TR. The semiconductor device 222 may include a memory circuit. Although not shown, the semiconductor device 222 may include a logic cell or a memory cell, which is formed on the bottom surface of the second semiconductor substrate 210, and may include a shallow device isolation pattern. In some example embodiments, the semiconductor device 222 may include a passive device, such as a capacitor.

The bottom surface of the second semiconductor substrate 210 may be covered with a device interlayer insulating layer 228. The device interlayer insulating layer 228 may be provided on the bottom surface of the second semiconductor substrate 210 to bury the semiconductor device 222. Here, the device interlayer insulating layer 228 may be provided to cover the semiconductor device 222. That is, the semiconductor device 222 may not be exposed to the outside by the device interlayer insulating layer 228. The device interlayer insulating layer 228 may be formed of or include at least one of silicon oxide (SiO), silicon nitride (SiN), or silicon oxynitride (SiON). In some example embodiments, the device interlayer insulating layer 228 may be formed of or include a low-k dielectric material. The device interlayer insulating layer 228 may have a single- or multi-layered structure. In the case where the device interlayer insulating layer 228 has the multi-layered structure, interconnection layers to be described below may be provided in insulating layers, respectively, and an etch stop layer may be interposed between the insulating layers. For example, the etch stop layer may be provided on a bottom surface of at least one of the insulating layers. The etch stop layer may be formed of or include at least one of, for example, silicon nitride (SiN), silicon oxynitride (SiON), or silicon carbonitride (SiCN).

The first interconnection portion 226 may be provided on a bottom surface of the device interlayer insulating layer 228. The first interconnection portion 226 may be provided in a lower portion of the device interlayer insulating layer 228 and may be exposed to the outside through the bottom surface of the device interlayer insulating layer 228. The first interconnection portion 226 may include horizontal interconnection patterns, which are used as a part of horizontal interconnection structure or pads. At least a portion (hereinafter, a first portion) of the first interconnection portion 226 may be connected to the bottom surface of the second via 230. Another portion (hereinafter, a second portion) of the first interconnection portion 226 may be disposed to be adjacent to the semiconductor device 222.

The second interconnection portion 224, which is connected to the transistor TR, may be provided in the device interlayer insulating layer 228. The second interconnection portion 224 may be placed between top and bottom surfaces of the device interlayer insulating layer 228. The second interconnection portion 224 may connect the second portion of the first interconnection portion 226 to the semiconductor device 222. The second interconnection portion 224 may include horizontal interconnection patterns for horizontal interconnection and vertical contacts for vertical interconnection.

The first and second interconnection portions 224 and 226 may be formed of or include, for example, copper (Cu) or tungsten (W).

The semiconductor device 222 (including the transistors TR), the device interlayer insulating layer 228, and the first and second interconnection portions 224 and 226 may constitute the second circuit layer 220.

The second vias 230 may be provided to vertically penetrate the second semiconductor substrate 210. The second vias 230 may be patterns, which are used for vertical interconnection. The second vias 230 may be provided to vertically penetrate the second semiconductor substrate 210 and the device interlayer insulating layer 228 and may be coupled to a top surface of the first portion of the first interconnection portion 226. The second vias 230 may be provided to vertically penetrate the device interlayer insulating layer 228 and the second semiconductor substrate 210 and may be exposed to the outside through the top surface of the second semiconductor substrate 210. The second vias 230 may be formed of or include, for example, tungsten (W).

The second lower pads 260 may be disposed on the device interlayer insulating layer 228. The second lower pads 260 may be disposed on the bottom surface of the device interlayer insulating layer 228. The second lower pads 260 may have a damascene structure. For example, the second lower pads 260 may further include a seed layer or a barrier layer, which is provided to cover side and bottom surfaces thereof. A planar area of the second lower pad 260 may be larger than a planar area of the second via 230. For example, a width of the second lower pads 260 may be larger than a width of the second vias 230. The second lower pads 260 may be vertically spaced apart from a bottom surface of the second circuit layer 220. The second lower pads 260 may include at least one of metallic materials. As an example, the second lower pads 260 may be formed of or include copper (Cu).

The second lower protection layer 270 may be disposed on the second circuit layer 220. For example, the second lower protection layer 270 may be provided on the bottom surface of the second circuit layer 220 to cover the first interconnection portions 226. The second lower protection layer 270 on the bottom surface of the second circuit layer 220 may enclose the second lower pads 260. The second lower pads 260 may be exposed to the outside of the second lower protection layer 270. For example, the second lower protection layer 270 may enclose the second lower pads 260 but may not cover the second lower pads 260, when viewed in a plan view. A bottom surface of the second lower protection layer 270 may be coplanar with bottom surfaces of the second lower pads 260. The second lower protection layer 270 may be in contact with the bottom surface of the second circuit layer 220. A thickness of the second lower protection layer 270 may be larger than a thickness of the second lower pads 260. In other words, the second lower pads 260 may be placed in a lower portion of the second lower protection layer 270. The second lower protection layer 270 may be formed of or include at least one of silicon nitride (SiN), silicon oxide (SiO), silicon oxycarbide (SiOC), silicon oxynitride (SiON), or silicon carbonitride (SiCN).

The second lower pads 260 may be horizontally shifted from the second vias 230. The following description will be given based on the second lower pad 260 and the second via 230 that are paired and electrically connected to each other. For example, the second lower pad 260 may not vertically overlap the second vias 230. As an example, when viewed in a plan view, a side surface of the second lower pad 260 may be spaced apart from side surfaces of the second vias 230. For example, a shift distance between the second lower pad 260 and the second via 230 may be larger than half the sum of a width of the second lower pad 260 and a width of the second vias 230. In the present specification, the shift distance between the second lower pad 260 and the second via 230 may mean a distance between a vertical center axis of the second lower pad 260 and a vertical center axis of the second via 230 in a horizontal direction. Here, a shift direction between the second lower pad 260 and the second vias 230 may be a horizontal direction.

A first interconnection pattern 262 may be provided in the second lower protection layer 270. When viewed in a vertical sectional view, the first interconnection pattern 262 may be placed between the second lower pads 260 and the second circuit layer 220. The first interconnection pattern 262 may electrically connect the second lower pads 260 to the first interconnection portions 226. The first interconnection pattern 262 may include horizontal interconnection patterns and vertical interconnection patterns. The vertical interconnection patterns may connect the horizontal interconnection patterns to each other, connect the horizontal interconnection patterns to the first interconnection portions 226, and connect the horizontal interconnection patterns to the second lower pads 260. The second lower pad 260 and the first interconnection portion 226 that are horizontally spaced apart from each other may be electrically connected to each other by the first interconnection pattern 262. In an example embodiment, a portion of the second lower protection layer 270 and the first interconnection pattern 262 that are placed between the second lower pad 260 and the second circuit layer 220 may correspond to an interconnection layer connecting the first interconnection portions 226 to the second lower pads 260.

The second upper pads 240 may be disposed on the top surface of the second semiconductor substrate 210. The second upper pads 240 may be connected to the second vias 230. For example, the second vias 230 may be provided to vertically penetrate the second semiconductor substrate 210 and may be coupled to bottom surfaces of the second upper pads 240. In other words, the second upper pads 240 may be vertically aligned to the second vias 230. A planar area of the second upper pad 240 may be larger than a planar area of the second via 230. For example, a width of the second upper pads 240 may be larger than the width of the second vias 230. The second upper pads 240 may include a metallic material. As an example, the second upper pads 240 may be formed of or include copper (Cu).

The second upper protection layer 250 may be disposed on the top surface of the second semiconductor substrate 210. The second upper protection layer 250 on the top surface of the second semiconductor substrate 210 may enclose the second upper pads 240. The second upper pads 240 may be exposed by the second upper protection layer 250. For example, the second upper protection layer 250 may enclose the second upper pads 240 but may not cover the second upper pads 240, when viewed in a plan view. A top surface of the second upper protection layer 250 may be coplanar with top surfaces of the second upper pads 240. The second upper protection layer 250 may be formed of or include at least one of high density plasma (HDP) oxide, undoped silicate glass (USG), tetraethyl orthosilicate (TEOS), silicon nitride (SiN), silicon oxide (SiO), silicon oxycarbide (SiOC), silicon oxynitride (SiON), or silicon carbonitride (SiCN). The second upper protection layer 250 may have a single- or multi-layered structure.

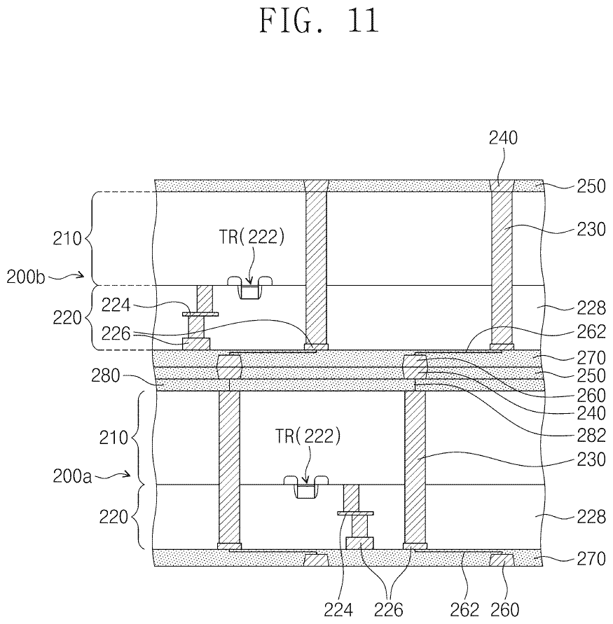

The second semiconductor chips 200, 200a, and 200b may have substantially the same structure. However, the uppermost one of the second semiconductor chips 200 of the chip stack CS may have a similar structure to the others of the second semiconductor chips 200. For example, the uppermost one of the second semiconductor chips 200 may include the second semiconductor substrate 210, the second circuit layer 220, the second lower pad 260, and the second lower protection layer 270. The uppermost second semiconductor chip 200 may not have the second via 230, the second upper pad 240, the second upper protection layer 250, and a redistribution layer 280 (see FIG. 11). However, the inventive concepts are not limited to this example. In an example embodiment, the uppermost one of the second semiconductor chips 200 may include at least one of the second via 230, the second upper pad 240, the second upper protection layer 250, and the redistribution layer 280. The uppermost one of the second semiconductor chips 200 may be thicker than the others of the second semiconductor chips 200.

The second semiconductor chips 200 may be sequentially mounted on top of each other. The mounting of the semiconductor chips 200 of the chip stack CS may be performed by the same method. Hereinafter, the mounting of the semiconductor chips 200 of the chip stack CS will be described with reference to an example of mounting one second semiconductor chip (hereinafter, an upper chip 200b) on another second semiconductor chip therebelow (hereinafter, a lower chip 200a).

The upper chip 200b may be disposed on the lower chip 200a. The second upper pads 240 of the lower chip 200a may face the upper chip 200b. The second upper pads 240 of the lower chip 200a may be vertically aligned to the second lower pads 260 of the upper chip 200b. The lower chip 200a and the upper chip 200b may be in contact with each other. The second vias 230 of the lower chip 200a may be horizontally shifted from the second vias 230 of the upper chip 200b. A shift distance between the second vias 230 of the lower chip 200a and the second vias 230 of the upper chip 200b may be larger than half the sum of a width of the second lower pads 260 and a width of the second vias 230. In addition, the second vias 230 of the lower chip 200a, the second upper pads 240 of the lower chip 200a, and the second lower pads 260 of the upper chip 200b may be vertically aligned to each other.

At an interface between the lower chip 200a and the upper chip 200b, the second upper protection layer 250 of the lower chip 200a may be bonded to the second lower protection layer 270 of the upper chip 200b. Here, the second upper protection layer 250 and the second lower protection layer 270 may form a hybrid bonding structure of oxide, nitride, or oxynitride. For example, the second upper protection layer 250 and the second lower protection layer 270 that are bonded to each other may have a continuous structure, and there may be no visible interface between the second upper protection layer 250 and the second lower protection layer 270. In other words, the second upper protection layer 250 and the second lower protection layer 270 may be provided as a single object. However, the inventive concepts are not limited to this example. The second upper protection layer 250 and the second lower protection layer 270 may be formed of or include different materials from each other. The second upper protection layer 250 and the second lower protection layer 270 may not have a continuous structure, and there may be a visible interface between the second upper protection layer 250 and the second lower protection layer 270.

The lower chip 200a may be bonded to the upper chip 200b. For example, the lower chip 200a and the upper chip 200b may be in contact with each other. At an interface between the lower chip 200a and the upper chip 200b, the second upper pads 240 of the lower chip 200a may be bonded to the second lower pads 260 of the upper chip 200b. For example, the second upper pads 240 and the second lower pads 260 may form an intermetal hybrid bonding structure. For example, the second upper pads 240 and the second lower pads 260 that are bonded to each other may have a continuous structure, and there may be no visible interface between the second upper pads 240 and the second lower pads 260. In other words, the second upper pad 240 and the second lower pad 260 may be provided as a single object.

According to an example embodiment of the inventive concepts, the second vias 230, which are respectively included in at least two or all of the second semiconductor chips 200, may be horizontally shifted from each other. In this case, stresses exerted on the second vias 230 in a vertical direction may not overlap each other. Thus, the stress exerted on the second vias 230 may be dispersed into the second upper protection layer 250 or the second lower protection layer 270. Accordingly, it may be possible to improve structural characteristics of the semiconductor package. Furthermore, it may be possible to mitigate or prevent a delamination issue between the second vias 230, the second upper pads 240, and the second lower pads 260 caused by the stresses and thereby enhancing the electric connection characteristics between the second vias 230, the second upper pads 240, and the second lower pads 260. That is, a semiconductor package with improved electrical characteristics may be provided.

Referring further to FIG. 9, the chip stack CS may be mounted on the first semiconductor chip 100. The chip stack CS may be disposed on the first semiconductor chip 100. The first upper pads 140 of the first semiconductor chip 100 may be vertically aligned to the second lower pads 260 of the lowermost one of the second semiconductor chips 200. A bonding structure between the lowermost one of the second semiconductor chips 200 and the first semiconductor chip 100 may be the same as or similar to the bonding structure between the second semiconductor chips 200. For example, the first semiconductor chip 100 may be in contact with the lowermost one of the second semiconductor chips 200, and at interface between the first semiconductor chip 100 and the lowermost one of the second semiconductor chips 200, the first upper pads 140 of the first semiconductor chip 100 may be bonded to the second lower pads 260 of the lowermost one of the second semiconductor chips 200. In some example embodiments, the lowermost one of the second semiconductor chips 200 may be mounted on the first semiconductor chip 100 in a flip-chip manner. For example, connection terminals (e.g., solder balls) may be provided for electric connection between the first upper pads 140 of the first semiconductor chip 100 and the second lower pads 260 of the lowermost one of the second semiconductor chips 200. In this case, an under-fill material may be provided in a space between the chip stack CS and the first semiconductor chip 100, and the under-fill material may enclose the connection terminals.

A mold layer 300 may be provided on the first semiconductor chip 100. The mold layer 300 may cover a top surface of the first semiconductor chip 100. The mold layer 300 may enclose the chip stack CS. For example, the mold layer 300 may cover side surfaces of the semiconductor chips 200. The mold layer 300 may protect the chip stack CS. The mold layer 300 may include an insulating material. For example, the mold layer 300 may be formed of or include an epoxy molding compound (EMC). Unlike the illustrated structure, the mold layer 300 may be formed to cover the chip stack CS. In other words, the mold layer 300 may cover a rear surface of the uppermost one of the second semiconductor chips 200.

In the description of the example embodiments to be explained below, an element previously described with reference to FIGS. 9 and 10 may be identified by the same reference number without repeating an overlapping description thereof, for concise description.

FIG. 11 is a sectional view illustrating a structure of semiconductor chips bonded to each other.

Referring to FIG. 11, a redistribution layer 280 may be provided between the second semiconductor substrate 210 and the second upper protection layer 250 of the lower chip 200a. The redistribution layer 280 may include a redistribution insulating layer and a redistribution pattern 282 in the redistribution insulating layer.

The redistribution insulating layer may cover the top surface of the second semiconductor substrate 210. The second upper protection layer 250 and the second upper pads 240 may be disposed on the redistribution insulating layer. That is, the second upper protection layer 250 and the second upper pads 240 may be vertically spaced apart from the second semiconductor substrate 210 and the second vias 230 by the redistribution insulating layer. The redistribution insulating layer may be formed of or include at least one of silicon nitride (SiN), silicon oxide (SiO), or silicon oxynitride (SiON).

The redistribution pattern 282 may be provided in the redistribution insulating layer. The redistribution pattern 282 may electrically connect the second vias 230 to the second upper pads 240. The redistribution pattern 282 may include interconnection patterns of various shapes (e.g., the second interconnection pattern 18 described with reference to FIG. 6). For example, the redistribution pattern 282 may include horizontal interconnection patterns for horizontal connection and vertical interconnection patterns for vertical connection. FIG. 11 illustrates an example, in which the redistribution layer 280 is provided in only the lower chip 200a, but the inventive concepts are not limited to this example. In an example embodiment, the redistribution layer 280 may be provided between the second semiconductor substrate 210 and the second upper protection layer 250 of the upper chip 200b, and all of the second semiconductor chips 200 (e.g., see FIG. 9) of the chip stack CS of the semiconductor package may have the redistribution layer 280.

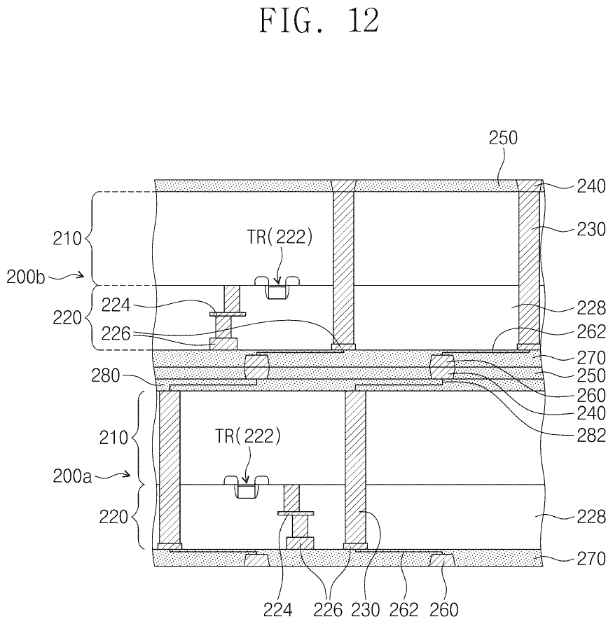

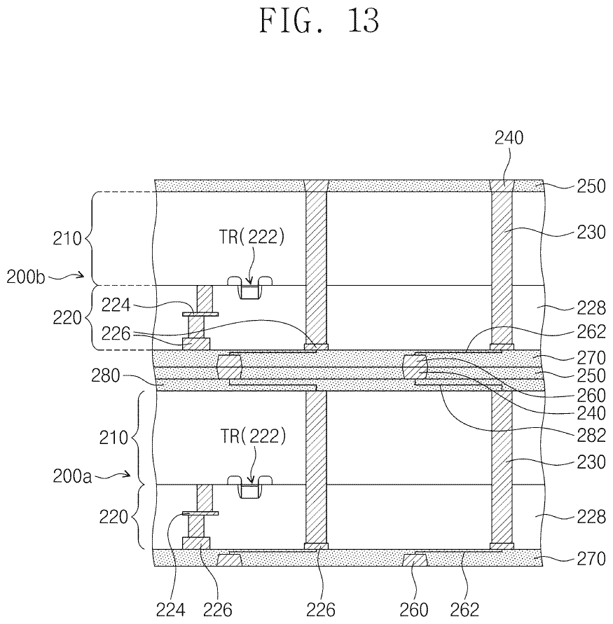

FIG. 12 is a sectional view illustrating a semiconductor package according to an example embodiment of the inventive concepts.

FIG. 11 illustrates an example, in which the second upper pads 240 of the lower chip 200a are vertically aligned to the second vias 230 of the lower chip 200a, but the inventive concepts are not limited to this example.

Referring to FIG. 12, the second vias 230 of the lower chip 200a may be horizontally shifted from the second upper pads 240 of the lower chip 200a. The following description will be given based on the second upper pad 240 and the second via 230 that are paired and electrically connected to each other. For example, the second upper pad 240 may not vertically overlap the second via 230. For example, a shift distance between the second upper pad 240 and the second via 230 may be larger than half the sum of a width of the second upper pad 240 and a width of the second via 230. Here, a shift direction between the second upper pad 240 and the second via 230 may be a horizontal direction.

The lower chip 200a and the upper chip 200b may be in contact with each other. At an interface between the lower chip 200a and the upper chip 200b, the second upper pads 240 of the lower chip 200a may be bonded to the second lower pads 260 of the upper chip 200b. The second upper pads 240 may be vertically aligned to the second lower pads 260. The second upper pads 240 and the second lower pads 260 may be horizontally spaced apart from the second vias 230 of the lower chip 200a and the second vias 230 of the upper chip 200b. Here, when viewed in a plan view, the second upper pad 240 and the second lower pad 260 that are paired to each other may be placed between the second via 230 of the lower chip 200a and the second via 230 of the upper chip 200b connected thereto.

FIG. 13 is a sectional view illustrating a semiconductor package according to an example embodiment of the inventive concepts.

FIG. 12 illustrates an example, in which the second upper pads 240 and the second lower pads 260 are placed between the second vias 230 of the lower chip 200a and the second vias 230 of the upper chip 200b when viewed in a plan view, but the inventive concepts are not limited to this example.

Referring to FIG. 13, the second vias 230 of the lower chip 200a may be vertically aligned to the second vias 230 of the upper chip 200b.

The second upper pads 240 of the lower chip 200a may be horizontally shifted from the second vias 230. For the second upper pad 240 and the second via 230 that are paired and electrically connected to each other, the second upper pad 240 may not vertically overlap the second via 230. A shift distance between the second upper pad 240 and the second via 230 may be larger than half the sum of a width of the second upper pad 240 and a width of the second via 230.

The second lower pads 260 of the upper chip 200b may be horizontally shifted from the second vias 230. For the second lower pad 260 and the second via 230 that are bonded and electrically connected to each other, the second lower pad 260 may not vertically overlap the second via 230. A shift distance between the second lower pad 260 and the second via 230 may be larger than half the sum of a width of the second lower pad 260 and a width of the second via 230.

The second upper pads 240 of the lower chip 200a may be vertically aligned to the second lower pads 260 of the upper chip 200b. Thus, a shift direction of the second upper pads 240 of the lower chip 200a from the second vias 230 may be the same as a shift direction of the second lower pads 260 of the upper chip 200b from the second vias 230.

Referring to FIGS. 13, the second vias 230 of the lower chip 200a and the second vias 230 of the upper chip 200b are vertically aligned to each other, and the second upper pads 240 of the lower chip 200a and the second lower pads 260 of the upper chip 200b are vertically aligned to each other. Respective sets of the second vias 230 of the lower chip 200a and the second vias 230 of the upper chip 200b are shifted from corresponding sets of the second upper pads 240 of the lower chip 200a and the second lower pads 260 of the upper chip 200b, respectively, in a direction parallel to a top surface of the lower chip 200a or the upper chip 220b by a distance that is 0.5 to 5 times the sum of a width of the second lower pad 260 and a width of the second via 230 or 0.5 to 5 times the sum of a width of the second upper pad 240 and a width of the second via 230.

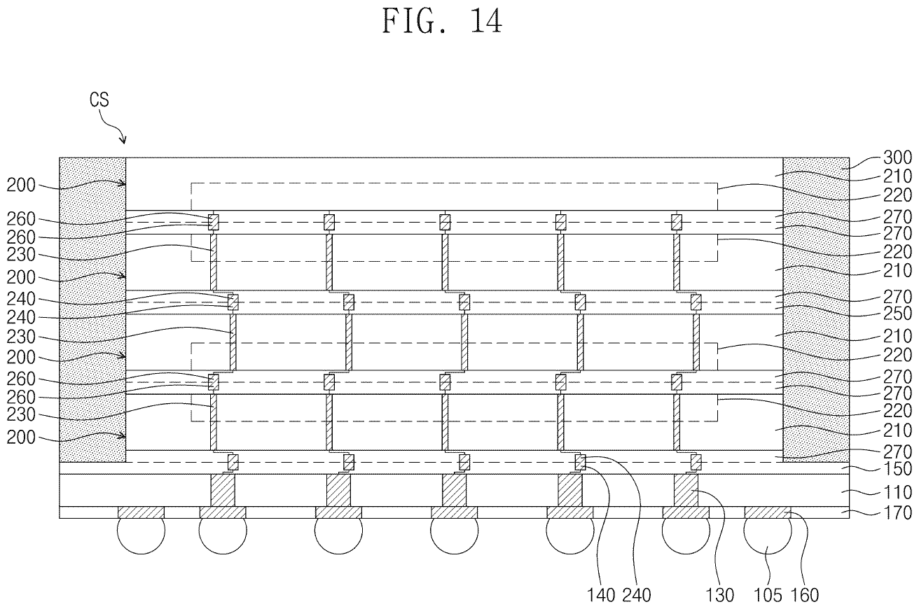

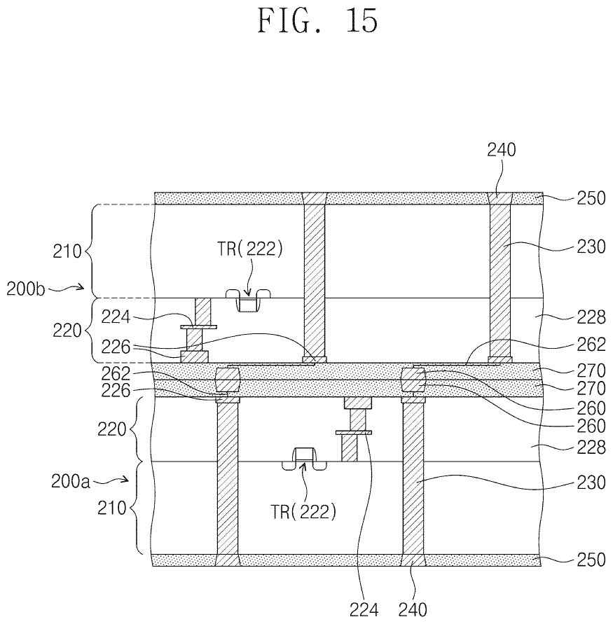

FIG. 14 is a sectional view illustrating a semiconductor package according to an example embodiment of the inventive concepts. FIG. 15 is a sectional view illustrating a structure of semiconductor chips bonded to each other.

FIG. 9 illustrates an example, in which active surfaces of all the second semiconductor chips 200 face the first semiconductor chip 100, but the inventive concepts are not limited to this example.

Referring to FIG. 14, the second semiconductor chips 200 may be stacked on the first semiconductor chip 100. In an example embodiment, a pair of the second semiconductor chips 200, which are adjacent to each other in a vertical direction, may be provided to have active surfaces facing each other. For example, the second semiconductor chips 200 may be bonded to each other in a face-to-face manner. In some example embodiments, the vertically adjacent pair of the second semiconductor chips 200 may be provided to have inactive surfaces facing each other. That is, the second semiconductor chips 200 may be bonded to each other in a back-to-back manner.

Hereinafter, the second semiconductor chips 200, 200a, and 200b will be described in more detail with reference to FIGS. 14 and 15. Although, in FIG. 15, lower and upper ones of the second semiconductor chips are identified with two different reference numbers 200a and 200b for distinction purpose, each of the second semiconductor chips 200a and 200b of FIG. 15 may correspond to the second semiconductor chip 200 of FIG. 14.

The upper chip 200b may be disposed on the lower chip 200a. An active surface of the lower chip 200a may face an active surface of the upper chip 200b. For example, the lower chip 200a and the upper chip 200b may be disposed in a face-to-face manner. The second lower pads 260 of the lower chip 200a may face the upper chip 200b. The second lower pads 260 of the lower chip 200a may be vertically aligned to the second lower pads 260 of the upper chip 200b. In other words, the lower chip 200a of FIG. 15 may be substantially the same as an inverted structure of the lower chip 200a of FIG. 10. The lower chip 200a and the upper chip 200b may be in contact with each other. The second vias 230 of the lower chip 200a may be horizontally shifted from the second vias 230 of the upper chip 200b. A shift distance between the second vias 230 of the lower chip 200a and the second vias 230 of the upper chip 200b may be larger than half the sum of a width of the second lower pads 260 and a width of the second vias 230. In addition, the second vias 230 of the lower chip 200a, the second lower pads 260 of the lower chip 200a, and the second lower pads 260 of the upper chip 200b may be vertically aligned to each other.

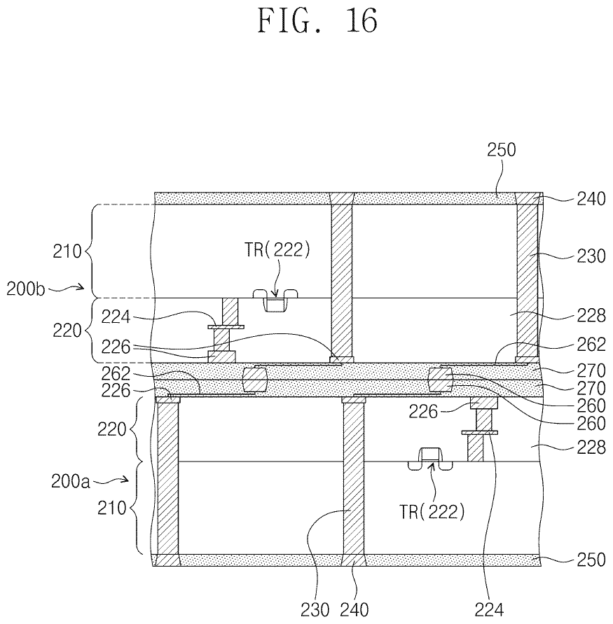

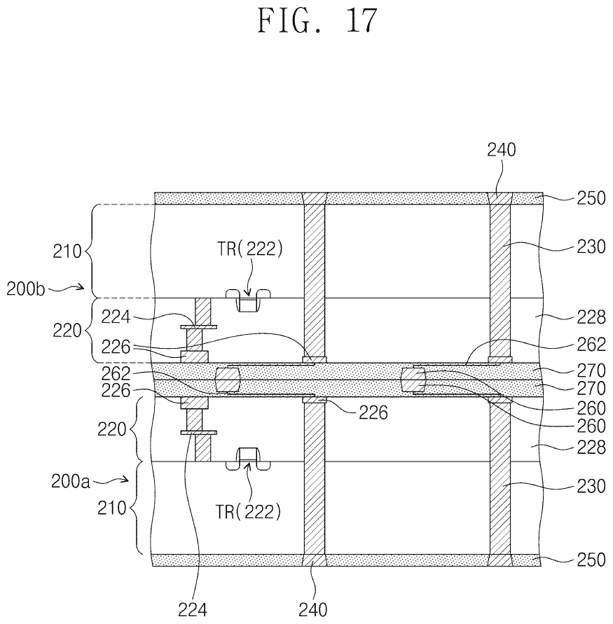

FIG. 16 is a sectional view illustrating a semiconductor package according to an example embodiment of the inventive concepts.

FIG. 15 illustrates an example, in which the second lower pads 260 of the lower chip 200a is vertically aligned to the second vias 230 of the lower chip 200a, but the inventive concepts are not limited to this example.

Referring to FIG. 16, the second vias 230 of the lower chip 200a may be horizontally shifted from the second lower pads 260 of the lower chip 200a. The second via 230 and the second lower pad 260 may be electrically connected to each other through the first interconnection pattern 262 therebetween. The following description will be given based on the second lower pad 260 and the second via 230 that are paired and electrically connected to each other. For example, the second lower pad 260 and the second via 230 may be vertically overlapped with each other. For example, a shift distance between the second lower pad 260 and the second via 230 may be larger than half the sum of a width of the second lower pad 260 and a width of the second via 230. Here, a shift direction between the second lower pad 260 and the second via 230 may be a horizontal direction.

The lower chip 200a and the upper chip 200b may be in contact with each other. At an interface between the lower chip 200a and the upper chip 200b, the second lower pad 260 of the lower chip 200a may be bonded to the second lower pads 260 of the upper chip 200b. The second lower pads 260 of the lower and upper chips 200a and 200b may be vertically aligned to each other. The second lower pads 260 of the lower and upper chips 200a and 200b may be horizontally spaced apart from the second vias 230 of the lower chip 200a and the second vias 230 of the upper chip 200b. Here, the second lower pads 260 of the lower and upper chips 200a and 200b that are paired to each other may be connected to the second vias 230 of the lower and upper chips 200a and 200b, respectively, and may be placed between the second vias 230 of the lower and upper chips 200a and 200b.

FIG. 17 is a sectional view illustrating a semiconductor package according to an example embodiment of the inventive concepts.

FIG. 16 illustrates an example, in which the second lower pads 260 are placed between the second vias 230 of the lower chip 200a and the second vias 230 of the upper chip 200b when viewed in a plan view, but the inventive concepts are not limited to this example.

Referring to FIG. 17, the second vias 230 of the lower chip 200a may be vertically aligned to the second vias 230 of the upper chip 200b.

The second lower pads 260 of the lower chip 200a may be horizontally shifted from the second vias 230. For the second lower pad 260 and the second via 230 that are paired and electrically connected to each other, the second lower pad 260 may not vertically overlap the second via 230. A shift distance between the second lower pad 260 and the second via 230 may be larger than half the sum of a width of the second lower pad 260 and a width of the second via 230.

The second lower pads 260 of the upper chip 200b may be horizontally shifted from the second vias 230. For the second lower pad 260 and the second via 230 that are paired and electrically connected to each other, the second lower pad 260 may not vertically overlap the second via 230. A shift distance between the second lower pad 260 and the second via 230 may be larger than half the sum of a width of the second lower pad 260 and a width of the second via 230.

The second lower pads 260 of the lower chip 200a and the second lower pads 260 of the upper chip 200b may be vertically aligned to each other. Thus, a shift direction of the second lower pads 260 of the lower chip 200a from the second vias 230 may be the same as a shift direction of the second lower pads 260 of the upper chip 200b from the second vias 230.

In a semiconductor package according to some example embodiments of the inventive concepts, first interconnection lines vertically penetrating a lower structure may be horizontally shifted from second interconnection lines vertically penetrating an upper structure. In this case, vertical stresses exerted on the first and second interconnection lines may not overlap with each other. For example, the stress exerted on the first interconnection lines may be dispersed into a first insulating layer, in a region on the first interconnection lines, or may be transferred to and dispersed into a second insulating layer through the second and first pads. The stress exerted on the second interconnection lines may be dispersed into the second insulating layer, in a region below the second interconnection lines. That is, the semiconductor package with improved structural characteristics may be provided. In addition, it may be possible to mitigate or prevent a delamination issue caused by the stresses between the first and second interconnection lines and the first and second pads, and thereby to improve the electric connection characteristics between the first and second interconnection lines and the first and second pads. That is, it may be possible to further improve electrical characteristics of the semiconductor package.

While some example embodiments of the inventive concepts have been particularly shown and described, it will be understood by one of ordinary skill in the art that variations in form and detail may be made therein without departing from the spirit and scope of the attached claims.

1. A semiconductor package, comprising:
a first semiconductor chip; and
a second semiconductor chip below the first semiconductor chip,
wherein the first semiconductor chip comprises,
a first semiconductor substrate,
a first semiconductor device on a bottom surface of the first semiconductor substrate,
a first interconnection layer on the bottom surface of the first semiconductor substrate,
a first via vertically penetrating the first semiconductor substrate and electrically connected to the first interconnection layer, and
a first pad on a bottom surface of the first interconnection layer,
wherein the second semiconductor chip comprises,
a second semiconductor substrate,
a second via vertically penetrating the second semiconductor substrate, and
a second pad on a top surface of the second semiconductor substrate and electrically connected to the second via, and
wherein the first semiconductor chip and the second semiconductor chip are in direct contact with each other,
the first pad and the second pad include a same material and constitute a single integral object,
the first and second vias are shifted from each other in a direction parallel to the bottom surface of the first semiconductor substrate, and
the first via is horizontally spaced apart from the first pad, when viewed in a plan view, and is electrically connected to the second pad through the first interconnection layer.

2. The semiconductor package of claim 1, wherein the first pad, the second pad, and the second via are vertically aligned to each other.

3. The semiconductor package of claim 1, wherein the first pad and the second pad are vertically aligned to each other, and
the first and second pads are spaced apart from the first and second vias, when viewed in a plan view.

4. The semiconductor package of claim 3, wherein the second semiconductor chip further includes a redistribution layer that is on the top surface of the second semiconductor substrate and electrically connects the second pad to the second via.

5. The semiconductor package of claim 1, wherein a shift distance between the first and second vias is larger than half a sum of a first width of the first via and a second width of the first pad.

6. The semiconductor package of claim 1, wherein the second semiconductor chip further comprises:
a second semiconductor device on a bottom surface of the second semiconductor substrate; and
a second interconnection layer on the bottom surface of the second semiconductor substrate,
wherein the second via connects the second interconnection layer to the second pad.

7. The semiconductor package of claim 1, wherein the second semiconductor chip further comprises:
a second semiconductor device on the top surface of the second semiconductor substrate; and
a second interconnection layer on the top surface of the second semiconductor substrate,
wherein the second via is electrically connected to the second pad through the second interconnection layer.

8. The semiconductor package of claim 1, wherein the first via, the second via, the first pad, and the second pad include a plurality of first vias, a plurality of second vias, a plurality of first pads, and a plurality of second pads, respectively,
each of the first vias is electrically connected to one of the second vias through the first pad and the second pad, and
each of the first pads is placed between two adjacent ones of the first vias.

9. The semiconductor package of claim 8, wherein each of the first pads is between side surfaces of the two adjacent ones of the first vias, when viewed in a plan view.

10. The semiconductor package of claim 8, wherein the first vias are arranged in a lattice shape, when viewed in a plan view, and
each of the first pads is between four adjacent ones of the first vias.

11. A semiconductor package, comprising:
a first semiconductor chip; and
a second semiconductor chip on the first semiconductor chip,
wherein the first semiconductor chip comprises,
a first semiconductor substrate;
a first semiconductor device on a bottom surface of the first semiconductor substrate;
a first interconnection layer on the bottom surface of the first semiconductor substrate;
a first via vertically penetrating the first semiconductor substrate and electrically connected to the first interconnection layer;
a redistribution layer on a top surface of the first semiconductor substrate; and
a first pad on a top surface of the redistribution layer,
wherein the second semiconductor chip comprises,
a second semiconductor substrate,
a second semiconductor device on a bottom surface of the second semiconductor substrate,
a second interconnection layer on the bottom surface of the second semiconductor substrate,
a second via vertically penetrating the second semiconductor substrate and electrically connected to the second interconnection layer, and
a second pad on a bottom surface of the second interconnection layer, and wherein the first via and the second via are vertically aligned to each other,
the first pad and the second pad are vertically aligned to each other, and
respective sets of the first and second vias are shifted from corresponding sets of the first and second pads, respectively, in a direction parallel to the top surface of the first semiconductor substrate by a distance that is 0.5 to 5 times a sum of a width of the first via and a width of the first pad or a sum of a width of the second via and a width of the second pad.

12. The semiconductor package of claim 11, wherein the first semiconductor chip and the second semiconductor chip are in direct contact with each other, and
the first pad and the second pad include a same material and constitutes a single integral object.

13. The semiconductor package of claim 11, wherein the first via is horizontally spaced apart from the first pad, when viewed in a plan view, and is electrically connected to the first pad through the redistribution layer, and
the second via is horizontally spaced apart from the second pad, when viewed in a plan view, and is electrically connected to the second pad through the second interconnection layer.

14. The semiconductor package of claim 11, wherein the first via, the second via, the first pad, and the second pad include a plurality of first vias, a plurality of second vias, a plurality of first pads, and a plurality of second pads, respectively,
each of the first vias is electrically connected to one of the second vias through the first pad and the second pad, and
each of the first pads is between two adjacent ones of the first vias.

15. The semiconductor package of claim 14, wherein each of the first pads is between side surfaces of the two adjacent ones of the first vias, when viewed in a plan view.

16. The semiconductor package of claim 14, wherein, when viewed in a plan view, the first vias are in a lattice shape, and
each of the first pads is placed between four adjacent ones of the first vias.

17. A semiconductor package, comprising:
a substrate;
a first semiconductor chip on the substrate;
a second semiconductor chip below the first semiconductor chip; and
a mold layer on the substrate and enclosing the first and second semiconductor chips,
wherein the first semiconductor chip comprises,
a first semiconductor substrate,
a first semiconductor device on a bottom surface of the first semiconductor substrate,
a first interconnection layer on the bottom surface of the first semiconductor substrate,
first vias vertically penetrating the first semiconductor substrate and electrically connected to the first interconnection layer, and
first pads on a bottom surface of the first interconnection layer,
wherein the second semiconductor chip comprises,
a second semiconductor substrate,
second vias vertically penetrating the second semiconductor substrate, and
second pads on a top surface of the second semiconductor substrate, and
wherein the first semiconductor chip and the second semiconductor chip are in direct contact with each other,
each of the first pads and a corresponding one of the second pads include a same material and constitutes a single integral object,
the first vias are in a lattice shape, and the first pads are in a lattice shape, when viewed in a plan view, and
each of the first pads is between four adjacent ones of the first vias.

18. The semiconductor package of claim 17, wherein the first vias and the second vias are shifted from each other in a direction parallel to the bottom surface of the first semiconductor substrate.

19. The semiconductor package of claim 18, wherein the first pads, the second pads and the second vias are vertically aligned to each other.

20. The semiconductor package of claim 18, wherein the first pads and the second pads are vertically aligned to each other, and
the first and second pads are spaced apart from the first vias and the second vias, when viewed in a plan view.

21.-23. (canceled)
